(19) United States
(12) Patent Application Publication
(10) Pub. No.: US 2024/0367178 A1
(43) Pub. Date: Nov. 7, 2024

(54) ELECTRO-FILTRATION DEVICES, COOLING SYSTEMS, AND METHOD FOR COOLING ELECTRONIC COMPONENTS

(71) Applicant: Wiwynn Corporation, New Taipei City (TW)

(72) Inventors: Tai-Ying TU, New Taipei City (TW); Tsung-Han LI, New Taipei City (TW); Zi-Ping WU, New Taipei City (TW); Ting-Yu PAI, New Taipei City (TW)

(73) Assignee: Wiwynn Corporation, New Taipei City (TW)

(21) Appl. No.: 18/391,628

(22) Filed: Dec. 20, 2023

Related U.S. Application Data
(60) Provisional application No. 63/500,313, filed on May 5, 2023.

(51) Int. Cl. B03C 5/02; B01D 36/02; H05K 7/20

(52) U.S. Cl. CPC B03C 5/02; B01D 36/02; H05K 7/20327

(57) ABSTRACT

A method for cooling electronic components includes: causing a flow of a portion of a cooling liquid from a cooling chamber through an electro-filtration device, in which the cooling chamber is configured to enable a thermal exchange between one or more electronic components and the cooling liquid housed in the cooling chamber; filtering at least a portion of the cooling liquid through the electro-filtration device, which is configured to apply one or more electric fields on the portion of the cooling liquid, the electro-filtration device having electrodes for providing the one or more electric fields while the portion of the cooling liquid flows through at least some of the one or more electric fields to result in a filtered cooling liquid; and causing a flow of the filtered cooling liquid from the electro-filtration device to the cooling chamber.

### CROSS-REFERENCE TO RELATED APPLICATION

The present application claims priority to U.S. Provisional Patent Application No. 63/500,313, filed on May 5, 2023, and entitled “AGGRESSIVE AND SCALABLE FILTRATION SYSTEM IN IMMERSION COOLING ENVIRONMENT,” the content of which is incorporated herein by reference in its entirety.

### TECHNICAL FIELD

The present disclosure generally relates to cooling systems. More particularly, the present disclosure relates to immersion cooling systems, filtration devices, or both in the immersion cooling systems.

### BACKGROUND

High-performance servers are becoming common in large-scale data centers and can produce significant amount of heat, which may affect the performance or function of the servers. Server systems usually rely on air cooling to transfer most of the heat. With the development of immersion cooling, servers or server blades or boards may be partially or completely immersed in a coolant liquid, which facilitates heat dissipation.

Using a two-phase immersion cooling system as an example, heat dissipation may occur through a cooling cycle like this: the coolant in liquid form vaporizes after being heated; the vaporized coolant condenses when cooled; and the coolant then returns to the cooling tank. The vaporized coolant may be cooled by cooling, condensation, or both by using cooling pipelines placed in a cooling tank. Operating through the vaporization-condensation cycle of the coolant, an immersion cooling system may facilitate the heat dissipation of multiple servers, devices, or components and may do so effectively by dissipating heat quickly. However, because the coolant used in immersion cooling is in contact with various electronic components and parts, there may be contaminants, particles, or materials in the liquid. Those contaminants, particles, or materials may be deposited, accumulated, or trapped on or near various electronic components and parts or server boards. Certain accumulated contaminants, particles, or materials, depending on its physical, chemical, or electrical characteristics, may result in undesired shorting of circuits, impact heat dissipation, affect cooling efficiency, or cause other undesirable effects.

### SUMMARY

Embodiments of the present disclosure provide a method for cooling electronic components. In some embodiments, the method includes: causing a flow of a portion of a cooling liquid from a cooling chamber through an electro-filtration device, in which the cooling chamber is configured to enable a thermal exchange between one or more electronic components and the cooling liquid housed in the cooling chamber; filtering at least a portion of the cooling liquid through the electro-filtration device, which is configured to apply one or more electric fields on the portion of the cooling liquid, the electro-filtration device having electrodes for providing the one or more electric fields while the portion of the cooling liquid flows through at least some of the one or more electric fields to result in a filtered cooling liquid; and causing a flow of the filtered cooling liquid from the electro-filtration device to the cooling chamber.

Embodiments of the present disclosure provide a cooling system. In some embodiments, the cooling system includes: a cooling chamber and a filtration chamber. The cooling chamber is configured to house at least a portion of a cooling liquid and one or more electronic components arranged along a stacking direction to enable a thermal exchange between the one or more electronic components and the portion of the cooling liquid in the cooling chamber. The filtration chamber is communicatively coupled to the cooling chamber and configured to receive the cooling liquid from the cooling chamber via an inlet portion of the filtration chamber, filter at least a portion of the cooling liquid through the filtration chamber to result in a filtered cooling liquid, and return the filtered cooling liquid in the filtration chamber to the cooling chamber via an outlet portion of the filtration chamber extending along a horizontal direction corresponding to the stacking direction.

Embodiments of the present disclosure provide an electro-filtration device. In some embodiments, the electro-filtration device includes: an inlet configured to receive a cooling liquid, electrodes providing one or more electric fields while a portion of the cooling liquid flows through at least some of the one or more electric fields to result in a filtered cooling liquid, and an outlet configured to release the filtered cooling liquid.

Additional features and advantages of the disclosed embodiments will be set forth in part in the following description, and in part will be apparent from the description, or may be learned by practice of the embodiments. The features and advantages of the disclosed embodiments may be realized and attained by the elements and combinations set forth in the claims.

### BRIEF DESCRIPTION OF THE DRAWINGS

Embodiments and various aspects of the present disclosure are illustrated in the following detailed description and the accompanying figures. It is noted that, in accordance with standard practice in the industry, various features are not drawn to scale. In fact, the dimensions of the various features may be arbitrarily increased or reduced for clarity of discussion.

FIG. 1 is a schematic view of an example immersion cooling system, consistent with some embodiments of the present disclosure.

FIG. 2 is a diagram illustrating the flow of the cooling liquid in the immersion cooling system of FIG. 1, consistent with some embodiments of the present disclosure.

FIG. 3 is a schematic view of another example immersion cooling system, consistent with some embodiments of the present disclosure.

FIG. 4A and FIG. 4B are diagrams illustrating example filters, consistent with some embodiments of the present disclosure.

FIG. 5 and FIG. 6 are diagrams respectively illustrating example electro-filtration devices, consistent with some embodiments of the present disclosure.

FIG. 7 and FIG. 8 are diagrams respectively illustrating multiple particle-filtering modules within example electro-filtration devices, consistent with some other embodiments of the present disclosure.

FIG. 9 is an example flowchart diagram of a method for cooling electronic components, consistent with some embodiments of the present disclosure.

### DETAILED DESCRIPTION

The following disclosure provides exemplary embodiments or examples for implementing various features. Examples of components and arrangements are described below to explain the present disclosure. These are merely examples and are not intended to be limiting. In addition, the present disclosure may repeat reference numerals and/or letters in the various examples. This repetition is for simplicity or illustration and does not in itself require any specific relationship between the various embodiments or configurations.

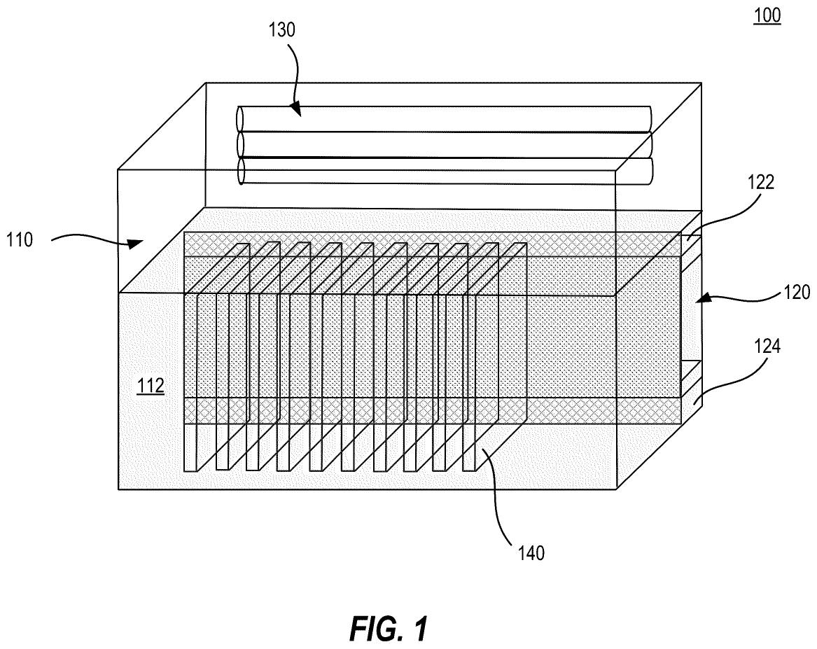

FIG. 1 is a schematic view of an example immersion cooling system 100, consistent with some embodiments of the present disclosure. In some embodiments, the immersion cooling system 100 includes one or more cooling chambers 110 (e.g., one or more cooling tanks), a filtration chamber 120, and a cooling medium 130. As shown in FIG. 1, the cooling chamber 110 is configured to house at least a portion of a cooling liquid 112 and one or more electronic components 140 (e.g., motherboards or server boards), to enable a thermal exchange between the electronic components 140 and the portion of the cooling liquid 112 in the cooling chamber 110.

The electronic components 140 may be heat generating components, such as a plurality of motherboards or server boards arranged along a stacking direction (e.g., the horizontal direction in FIG. 1). The electronic components 140 are disposed in the cooling chamber 110 and immersed in the cooling liquid 112. For example, server boards may be secured onto a closed or semi-closed bracket and installed in the cooling chamber 110. The cooling liquid 112 may flow through an opening at a bottom portion of the bracket or flow through gaps between adjacent brackets within the cooling chamber 110 to pass through the motherboards or server boards.

In some embodiments, the liquid level of the cooling liquid 112 may be higher (e.g., by about 2 to 3 mm) than the electronic components 140 to facilitate the thermal exchange. In some embodiments, the cooling medium 130 arranged within the cooling chamber 110 may include one or more condensation pipelines or other condensation structures disposed in a space above the cooling liquid 112 within the cooling chamber 110. Accordingly, the electronic components 140 can be cooled through a vaporization of a heated portion of the cooling liquid 112 in the cooling chamber 110, and through a condensation of a vaporized cooling liquid back into a liquid state by the cooling medium 130.

For example, the cooling medium 130 may include condensation pipelines or various condensation structures in the space of the immersion cooling system 100. The vaporized cooling liquid is cooled by the condensate or material flowing in the condensation pipelines or structures having a relatively low temperature, and condenses into liquid on the cooling medium 130. In some embodiments, the condensate or material in the condensation pipelines or structures absorbs the heat energy, flows out of the immersion cooling system 100 to remove the heat by an external heat exchange mechanism, and then flows back to the condensation pipelines or structures to achieve the circulation. Liquid droplets condensing on the condensation pipelines or structures fall back into the cooling liquid 112 in the cooling chamber 110 by gravity, achieving the circulation.

In some embodiments, the immersion cooling system 100 may include a cover configured to seal the containing space of the immersion cooling system 100, allowing the cooling liquid 112 to perform the circulation described above in the sealed containing space. In addition, the cover may be opened to facilitate maintenance of the electronic components 140 or to deploy or replace the electronic components 140 in the immersion cooling system 100.

As shown in FIG. 1, the filtration chamber 120 may be communicatively coupled to the cooling chamber 110. In various embodiments, the filtration chamber 120 may be coupled to the cooling chamber 110 in different ways. For examples, the filtration chamber 120 may be detachably attached to the cooling chamber 110, but the present disclosure is not limited to such configuration. The filtration chamber 120 is configured to receive the cooling liquid 112 from the cooling chamber 110 via an inlet portion 122 of the filtration chamber 120, and filter at least a portion of the cooling liquid 112 through the filtration chamber 120 to result in a filtered cooling liquid. The filtered cooling liquid in the filtration chamber 120 flows back to the cooling chamber 110 via an outlet portion 124 of the filtration chamber 120. In some embodiments, the inlet portion 122 and the outlet portion 124 of the filtration chamber 120 extend along a horizontal direction corresponding to the stacking direction. For example, the inlet portion 122 and the outlet portion 124 of the filtration chamber 120 may extend along the horizontal direction that is generally parallel to the stacking direction of the electronic components 140. It is understood that the design illustrated in FIG. 1 is merely an example and the disclosure is not limited thereto. For example, while one cooling chamber 110 is illustrated in FIG. 1, the number of the cooling chambers within the immersion cooling system 100 may be any appropriate numbers in various embodiments.

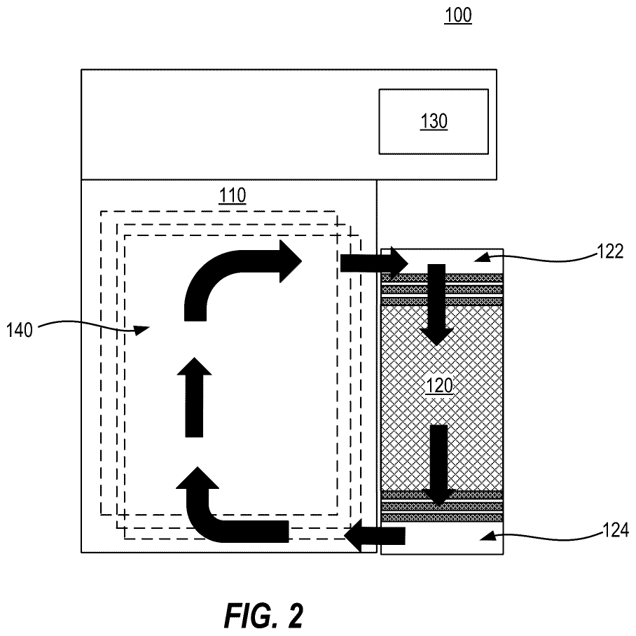

FIG. 2 is a diagram illustrating the flow of the cooling liquid 112 between the cooling chamber 110 and the filtration chamber 120 in the immersion cooling system 100 of FIG. 1, consistent with some embodiments of the present disclosure. In some embodiments, one of the inlet portion 122 or the outlet portion 124 is communicatively coupled to a bottom portion of the cooling chamber 110, and another one of the inlet portion 122 or the outlet portion 124 is communicatively coupled to a top portion of the cooling chamber 110. For example, in the embodiments of FIG. 1 and FIG. 2, the outlet portion 124 is communicatively coupled to the bottom portion of the cooling chamber 110, and the inlet portion 122 is communicatively coupled to the top portion of the cooling chamber 110. Accordingly, during the operations, the cooling liquid 112 flows into the filtration chamber 120 and moves vertically downward through the filtration chamber 120. In the filtration chamber 120, the cooling liquid 112 is filtered to remove contamination and/or particles. After the filtration process, the filtered cooling liquid flows back to the cooling chamber 110 via the outlet portion 124.

In view of the above, by the arrangements shown in FIG. 1 and FIG. 2, the main liquid flow direction within the cooling chamber 110 may be in substantially parallel (e.g., within 10 degrees, 5 degrees, or 1 degree) to the electronic components 140 (e.g., motherboards). Compared to existing solutions where the flow direction may be generally perpendicular to the motherboards, the electronic components 140 in the immersion cooling system 100 of FIGS. 1 and 2 do not become obstacles impeding the liquid flow and resulting in contaminant accumulation along the liquid flow direction. Accordingly, a generally uniform distribution of the contaminants along a horizontal cross-section of the cooling chamber 110 can be achieved. Thus, the electronic components 140 within the cooling chamber 110 maintain a uniform contamination level, and the accumulation of the contaminants in certain spots can be reduced.

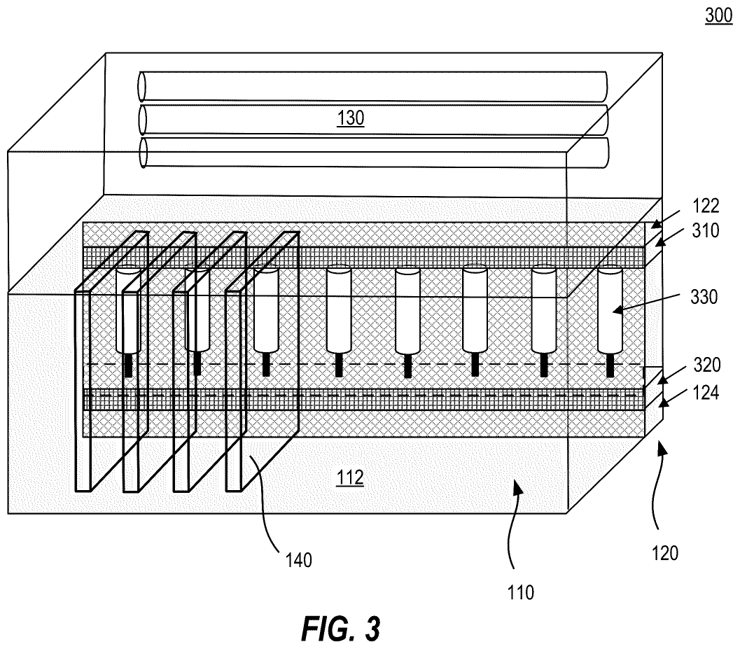

FIG. 3 is a schematic view of another example immersion cooling system 300, consistent with some embodiments of the present disclosure. As shown in FIG. 3, in some embodiments, the filtration chamber 120 may include an electro-filtration device having filters 310 and 320, and multiple particle-filtering media 330 arranged between the filters 310 and 320. In some embodiments, the filtration chamber 120 may further include one or more pumps configured to drive the cooling liquid 112 and facilitate the circulation of the cooling liquid 112. Specifically, the pump(s) may be configured to cause the flow of the filtered cooling liquid 112 in the filtration chamber 120 back to the cooling chamber 110 via the outlet portion 124 of the filtration chamber 120. In some embodiments, the pumps can be disposed at a bottom part of the filtration chamber 120, but the present disclosure is not limited thereto. For example, the pump(s) can also be integrated with the particle-filtering media 330, and the flow of the cooling liquid 112 may be pumped from the bottom to the top of the particle-filtering media 330, or pumped from the top to the bottom of the particle-filtering media 330.

The filters 310 and 320 are configured to apply one or more electric fields on the portion of the cooling liquid flowing through the filter 310 and 320, to prevent the phenomenon of electrochemical migration (ECM) on the electronic components 140. ECM refers to the dissolution and movement of metal ions in presence of electric potential, which results in the growth of dendritic structures. In a two-phase immersion cooling environment (e.g., immersion cooling system 100 in FIG. 1), contamination and halogen (e.g., Bromine) in the cooling liquid are two key factors triggering the ECM. Specifically, in the immersion cooling system 100, the electronic components 140 (e.g., motherboards with IC chips) produces heat to vaporize the cooling liquid 112. When the cooling liquid 112 is changed to a gaseous state by vaporization, the contamination is deposited at areas adjacent to solder balls of the circuit boards. Due to plasticizers (e.g., Dicotyl Terephthalate, DOTP) used in the manufacture of the circuit boards, mobilized Bromine ions may react with the solder balls to form Tin Dibromide (SnBr₂) and resulted in the growth of dendritic structures from a cathode (e.g., a ground pin) to an anode (e.g., a voltage source pin) on the circuit boards.

By the arrangement of the filters 310 and 320 in the filtration chamber 120, ions resulting the growth of dendritic structures can be attracted by the electric fields provided by the filters 310 and 320. In other words, the filters 310 and 320 induce the growth of dendritic structures within the filters 310 and 320 to prevent the ion accumulation and migration and the growth of dendritic structures on the electronic components 140.

The particle-filtering media 330 arranged in the filtration chamber 120 are configured to filter other particles before or after the cooling liquid flowing through the filters 310 or 320. In this way, impurities in the cooling liquid 112 may be reduced effectively, in order to maintain the heat dissipation capacity.

It is understood that the design illustrated in FIG. 3 is merely an example. For example, the filtration chamber 120 shown in FIG. 3 includes two filters 310 and 320, but the disclosure is not limited thereto. In other embodiments, the immersion cooling system 300 may include a single filter, and the particle-filtering media 330 may be configured to filter particles in the cooling liquid before the cooling liquid flows into the filter, or filter particles in the filtered cooling liquid after the filtered cooling liquid exits from the filter. In some other embodiments, the particle-filtering media 330 may be optional particle filter modules combined with pumps, and can be easily replaced or removed from the filtration chamber 120. The number of the particle filter modules may be any appropriate numbers in various embodiments.

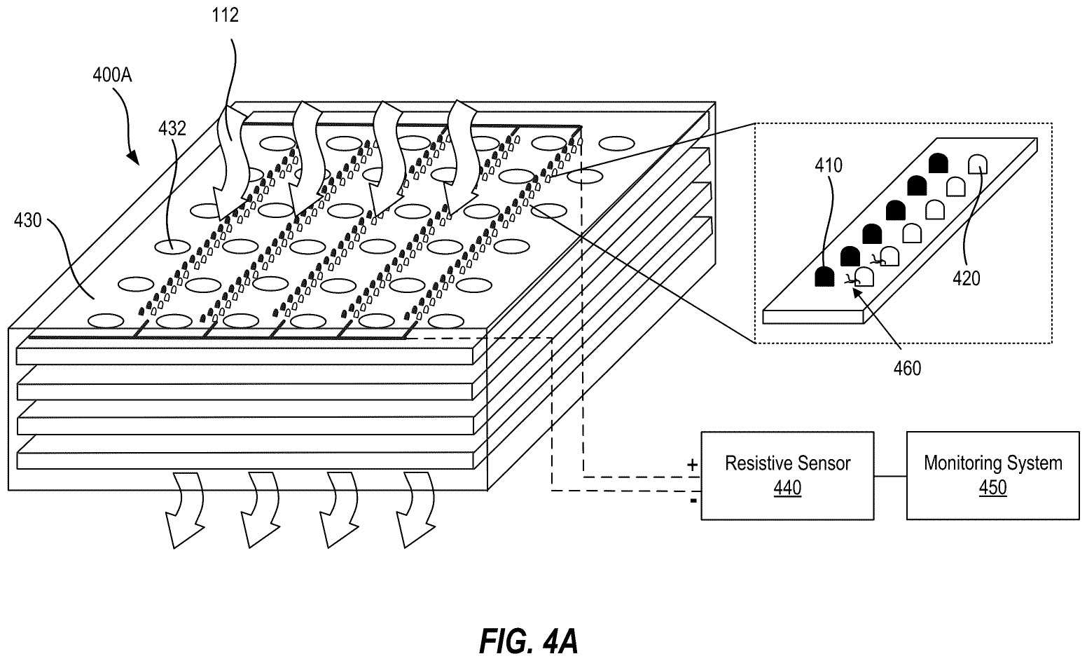

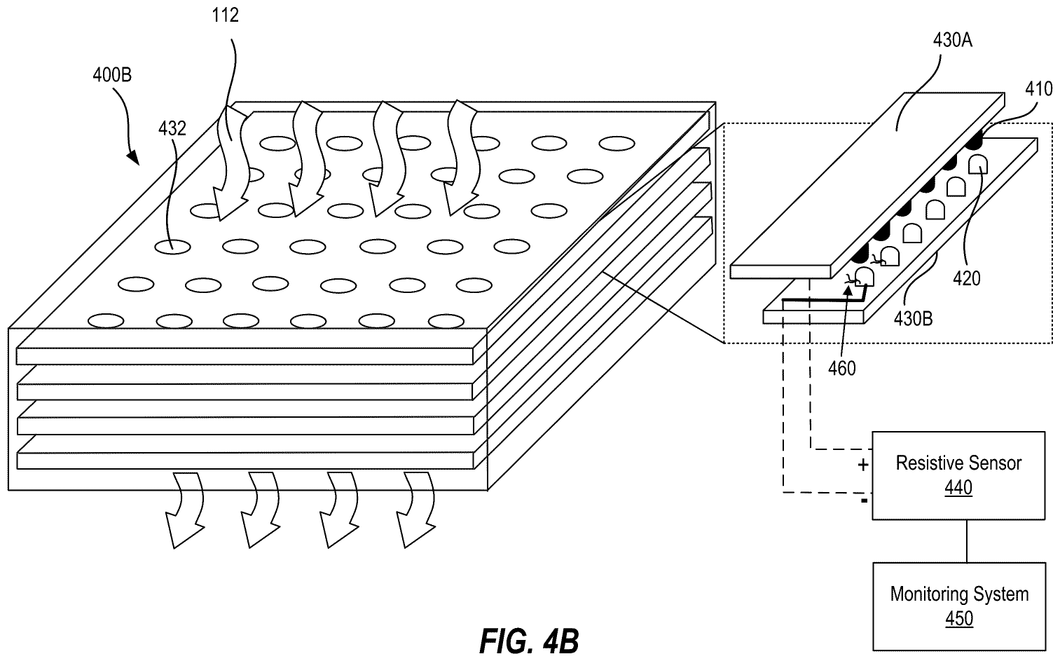

FIG. 4A is a diagram illustrating an example filter 400A, consistent with some embodiments of the present disclosure. The filter 400A includes an inlet configured to receive the cooling liquid, an outlet configured to release the filtered cooling liquid, and a plurality of electrodes 410, 420 as anodes and cathodes. The electrodes 410 and 420 are configured to provide the one or more electric fields. Accordingly, the portion of the cooling liquid flows through at least some of the one or more electric fields to result in the filtered cooling liquid.

As shown in the embodiments of FIG. 4A, the filter 400A may include multiple substrates 430 stacked together. For example, the substrates 430 may be layers of printed circuit boards (PCBs), but the present disclosure is not limited thereto. In various embodiments, the substrates 430 may be made of any material and in any form providing a base for electrodes. In some embodiments, at least one of the substrates 430 is perforated to provide through-holes 432 extending from a top surface to a bottom surface of the substrate 430, for the cooling liquid 112 to flow through the substrate 430. The electrodes 410 and 420 are arranged on one or more of the substrates 430. For examples, the electrodes 410 and 420 may be arranged in arrays on the same substrate 430 to provide alternating anodes and cathodes across neighboring electrodes on the same substrate 430, but the present disclosure is not limited thereto.

FIG. 4B is a diagram illustrating another example filter 400B, consistent with some embodiments of the present disclosure. As shown in FIG. 4B, the electrodes 410 and 420 may also include alternating anodes and cathodes across neighboring substrates 430A and 430B. For example, a first substrate 430A may include multiple anode electrodes 410, and a second substrate 430B above or below the first substrate 430A may include multiple cathode electrodes 420 to provide one or more electric fields between two neighboring substrates. In some other embodiments, the electrodes 410 and 420 may also include alternating anodes and cathodes both across the neighboring substrates and the neighboring electrodes on the same substrate.

In the filter 400A or the filter 400B, when an electrical potential difference exists across a pair of electrodes 410 and 420, which may be on the same substrate 430 or on two neighboring substrates 430A and 430B, an electric field occurs and induces the dendritic structures to grow from the cathode on the substrates 430 or 430B. Thus, the ions causing the dendritic structures are captured by these stacked dummy circuit boards, and removed from the cooling liquid 112. In some embodiments, in order to induce the dendritic structures to grow within the filter 400A or 400B, instead of growing on the electronic components 140 in the cooling chamber 110, a magnitude of the electric field(s) provided by the filter 400A or 400B is no less than a threshold value reflecting an electric field caused by the electronic components 140 in the cooling chamber 110. For example, a magnitude of the electric field(s) may be greater than or equal to 50 volts per millimeter to efficiently induce the electrochemical migration within the filter 400A or 400B. Accordingly, the arrangement of the electrodes 410 and 420 may be designed based on actual needs in different applications to facilitate the filtration. For example, a distance between a pair of electrodes 410 and 420 may be within about 0.3 millimeters to about 0.6 millimeters.

As shown in FIG. 4A and FIG. 4B, in some embodiments, the electro-filtration device in the immersion cooling system 100 or 300 may include a resistive sensor 440 and a monitoring system 450 electrically coupled to the resistive sensor 440. For example, electrodes 410 and 420 within the filter 400A or 400B can be coupled to the external resistive sensor 440. The resistive sensor 440 is configured to measure a resistance between at least one pair of electrodes 410 and 420, so that a measured resistance between the pair of electrodes 410 and 420 can be compared with a threshold resistance value to identify a condition of the electro-filtration device. For example, the monitoring system 450 may be configured to provide an indication in response to a measured resistance between the pair of electrodes 410 and 420 being lower than a threshold resistance value. The monitoring system 450 may be configured to receive the resistance measured by the resistive sensor 440, and detect potential growth of dendrites 460 accordingly.

As the dendrites 460 grow toward the anodes over time and cause a reduction of the resistance or a short circuit event between electrodes 410 and 420, the monitoring system 450 may, based on the monitored resistance lower than the threshold, output a notification signal (e.g., in the form of light, sound, etc.) or provide a warning message to notify an operator, so the operator may replace the filter 400A or 400B in time to maintain the optimal filtration efficiency.

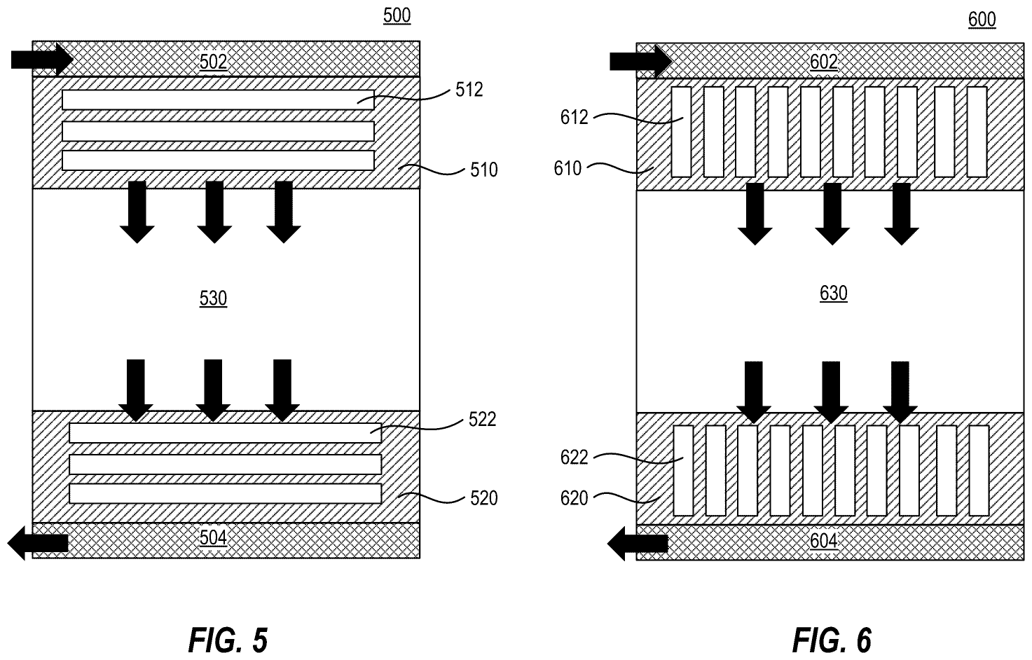

In various embodiments, the substrates 430, 430A, and 430B in the filter 400A or 400B may be stacked along a horizontal direction or along a vertical direction. FIG. 5 and FIG. 6 are diagrams respectively illustrating example electro-filtration devices 500 and 600, consistent with some embodiments of the present disclosure. As shown in FIG. 5, the electro-filtration device 500 includes an inlet 502 configured to receive the cooling liquid 112 and an outlet 504 configured to release the cooling liquid 112, and the cooling liquid 112 flows through filters 510 and 520, and a particle-filtering medium 530 arranged between the filters 510 and 520 in the electro-filtration device 500. In the filters 510 and 520, substrates 512 and 522 (e.g., PCBs) are placed horizontally (e.g., stacked along a vertical axis) and configured to provide electric fields by applying electrical potential differences across pairs of electrodes.

As previously discussed in the embodiments of FIG. 4A, the substrates 512 and 522 may be perforated to provide through-holes for the cooling liquid 112 to flow downwardly through the substrates 512 and 522 efficiently. The particle-filtering medium 530 may be arranged between a first subset of the electrodes (e.g., electrodes on substrates 512 in FIG. 5) providing the electric field(s) and a second subset of the electrodes (e.g., electrodes on substrates 522 in FIG. 5) providing the electric field(s).

Similarly, the electro-filtration device 600 in FIG. 6 also includes an inlet 602 configured to receive the cooling liquid 112 and an outlet 604 configured to release the cooling liquid 112, and the cooling liquid 112 flows through filters 610 and 620, and a particle-filtering medium 630 arranged between the filters 610 and 620 in the electro-filtration device 600. In the electro-filtration device 600, substrates 612 and 622 (e.g., PCBs) in the filters 610 and 620 are placed vertically (e.g., stacked along a horizontal axis) and configured to provide electric fields by applying electrical potential differences across pairs of electrodes. In some embodiments, the substrates 612 and 622 are not perforated, but the present disclosure is not limited thereto. As shown in the embodiments of FIGS. 5 and 6, a planar direction of the substrates 512, 522, 612, and 622 may be generally either parallel or perpendicular with a direction (e.g., a downward direction) of a flow of the cooling liquid 112 within the filters 510, 520, 610, and 620.

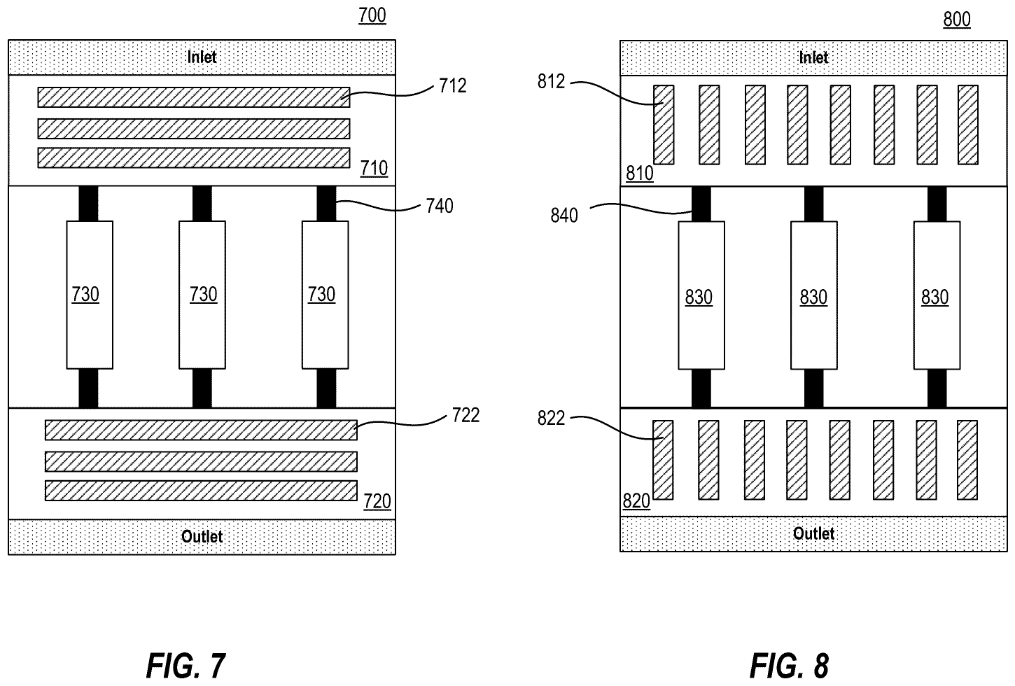

FIG. 7 and FIG. 8 are diagrams respectively illustrating multiple particle-filtering modules within example electro-filtration devices 700 and 800, consistent with some other embodiments of the present disclosure. Compared to the electro-filtration devices 500 and 600 above, as shown in FIG. 7, filters 710 and 720 include corresponding housings forming an enclosure for confinement of substrates 712 and 722, and multiple particle-filtering modules 730 are communicatively coupled between the filters 710 and 720 via corresponding Quick Connectors (QCs) 740. Similarly, as shown in FIG. 8, filters 810 and 820 include corresponding housings forming an enclosure for confinement of substrates 812 and 822, and multiple particle-filtering modules 830 are communicatively coupled between filters 810 and 820 via corresponding Quick Connectors (QCs) 840. Accordingly, any of the particle-filtering modules 730 and 830 can be easily and independently removed and replaced when it becomes aged or a maintenance need arises, without interference to other particle-filtering modules 730 or 830.

In view of the above, the electro-filtration devices 500-800 provided in the embodiments of FIG. 5-FIG. 8 can aggressively attract ions (e.g., Bromine ions) on the electric filters by applying moderate electrical fields, and prevent ECM phenomenon on the electronic components 140 (e.g., motherboards). In addition, a resistive sensor can be used to detect the growth of dendrites based on the monitored resistance across electrode pairs, so as to notify or alert an operator when a replacement is required.

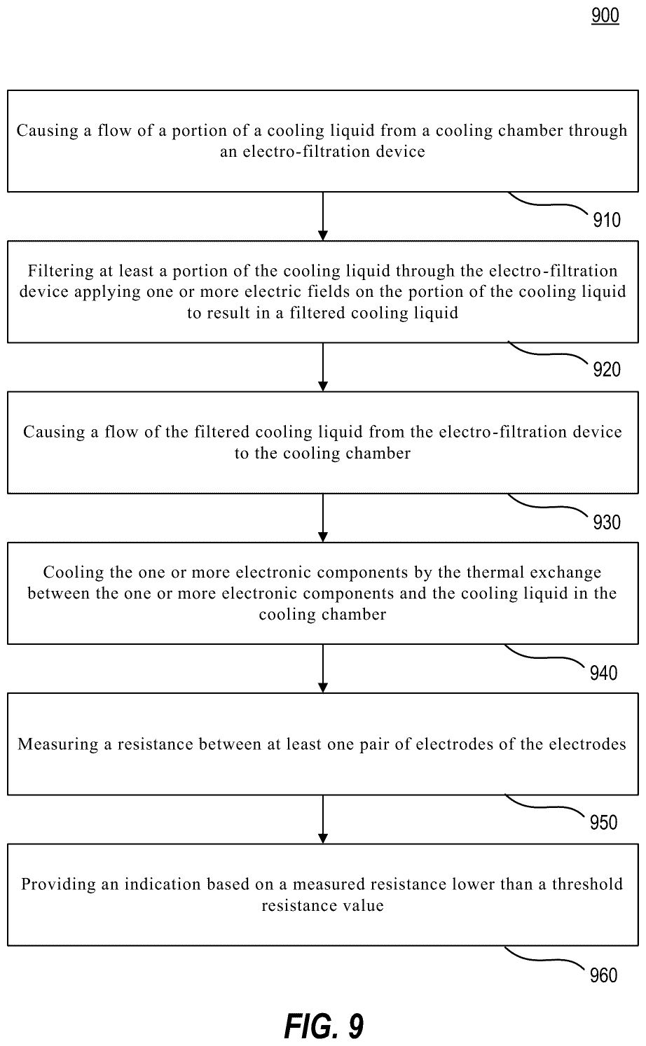

FIG. 9 is an example flowchart diagram of a method 900 for cooling electronic components, consistent with some embodiments of the present disclosure. Method 900 can be performed by an immersion cooling system (e.g., immersion cooling system 100 or 300 in FIGS. 1-3), but the present disclosure is not limited thereto. The method 900 includes steps 910, 920, and 930.

In step 910, the immersion cooling system causes a flow of a portion of a cooling liquid (e.g., cooling liquid 112 in FIG. 1) from a cooling chamber (e.g., cooling chamber 110 in FIG. 1) through an electro-filtration device (e.g., any of electro-filtration devices 500, 600, 700, or 800 in FIGS. 5-8). The cooling chamber is configured to enable a thermal exchange between one or more electronic components (e.g., electronic components 140 in FIG. 1) and the cooling liquid housed in the cooling chamber.

In step 920, the immersion cooling system filters at least a portion of the cooling liquid through the electro-filtration device to result in a filtered cooling liquid. In some embodiments, the electro-filtration device applies one or more electric fields on the portion of the cooling liquid with electrodes (e.g., electrodes 410, 420 in FIG. 4A) providing the one or more electric fields while the portion of the cooling liquid flows through at least some of the one or more electric fields. In some embodiments, a magnitude of the one or more electric fields is greater than or equal to a threshold value reflecting an electric field caused by the one or more electric components in the cooling chamber.

For example, in step 920, the portion of the cooling liquid that left the cooling chamber may flow through a plurality of substrates (e.g., substrates 430 in FIG. 4A). The electrodes providing the electric field(s) are arranged on the substrates. The substrates may have alternating anodes and cathodes across neighboring substrates, across neighboring electrodes on the same substrate, or both across the neighboring substrates and the neighboring electrodes. In some embodiments, the substrates may have a planar direction generally parallel or perpendicular with a direction of the flow of the portion of the cooling liquid that left the cooling chamber. In some embodiments, the cooling liquid may flow through one or more substrates by passing through through-holes extending from a top surface to a bottom surface of the one or more substrates.

In some embodiments, the step 920 further includes flowing the cooling liquid that left the cooling chamber through a particle-filtering medium (e.g., any of particle-filtering medium 530, 630 or particle-filtering modules 730, 830 in FIGS. 5-8) to filter particles in the cooling liquid that left the cooling chamber.

In step 930, the immersion cooling system causes a flow of the filtered cooling liquid from the electro-filtration device to the cooling chamber.

In some embodiments, the method 900 further includes step 940. In step 940, the immersion cooling system cools the one or more electronic components by the thermal exchange between the one or more electronic components and the cooling liquid in the cooling chamber. For example, the immersion cooling system may cool the one or more electronic components through a vaporization of a heated portion of the cooling liquid in the cooling chamber and through a condensation of a vaporized cooling liquid back into a liquid state by a cooling medium (e.g., cooling medium 130 in FIG. 1) arranged within the cooling chamber.

In some embodiments, the method 900 further includes steps 950 and 960. In step 950, the immersion cooling system measures a resistance between at least one pair of electrodes of the electrodes. In step 960, the immersion cooling system provides an indication based on a measured resistance lower than a threshold resistance value.

Details of the operations of steps 910-960 have been discussed in the above embodiments and thus are not repeated herein for the sake of brevity. It is noted that the method 900 shown in FIG. 9 is merely an example and not meant to limit the present disclosure. For example, some steps described in the method 900 may be optional, and the sequence of steps shown in FIG. 9 are only for illustrative purposes and are not intended to be limited to any particular sequence of steps. As such, those skilled in the art can appreciate that these steps can be skipped, or performed in a different order or in parallel while implementing the method. It is understood that additional operations may be performed before, during, and/or after the method 900 depicted in FIG. 9, and that some other processes may only be briefly described herein.

In summary, various electro-filtration devices, cooling systems, and methods for cooling electronic components are provided to prevent the phenomenon of the electrochemical migration and the damages to the circuit boards immersed in the cooling systems. By adjusting the liquid flow direction within the cooling chamber, the contaminant accumulation in blind spot regions can be reduced or avoided. In addition, the undesired short circuits and damages to components on the motherboards can be prevented by applying electric fields to induce the ECM within electric filters of the electro-filtration devices.

In the foregoing specification, embodiments have been described with reference to numerous specific details that can vary from implementation to implementation. Certain adaptations and modifications of the described embodiments can be made. It is appreciated that certain features of the specification, which are, for clarity, described in the context of separate embodiments, may also be provided in combination in a single embodiment. Conversely, various features of the specification, which are, for brevity, described in the context of a single embodiment, may also be provided separately or in any suitable sub-combination or as suitable in any other described embodiment of the specification. Certain features described in the context of various embodiments are not to be considered essential features of those embodiments unless the embodiment is inoperative without those elements.

The terms used in this specification generally have their ordinary meanings in the art and in the specific context where each term is used. The examples in this specification, including examples of any terms discussed herein, are illustrative only, and in no way limit the scope and meaning of the disclosure or of any exemplified term. Likewise, the present disclosure is not limited to various embodiments.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this document, the term “coupled” may also be termed as “electrically coupled”, and the term “connected” may be termed as “electrically connected”. “Coupled” and “connected” may also be used to indicate that two or more elements cooperate or interact with each other.

Depending on the context, the term “if” and “supposed” used herein can be interpreted as “when” or “while” or “in response to a determination” or “in response to a recognition.” Similarly, depending on the context, the phrases “if it is determined that” or “if it is recognized that” may be interpreted as “when it is determined” or “in response to a determination” or “when it is recognized that” or “in response to a recognition of.”

The embodiments may further be described using the following clauses:
1: A method for cooling electronic components, the method comprising: causing a flow of a portion of a cooling liquid from a cooling chamber through an electro-filtration device, wherein the cooling chamber is configured to enable a thermal exchange between one or more electronic components and the cooling liquid housed in the cooling chamber; filtering at least a portion of the cooling liquid through the electro-filtration device, which is configured to apply one or more electric fields on the portion of the cooling liquid, the electro-filtration device having a plurality of electrodes for providing the one or more electric fields while the portion of the cooling liquid flows through at least some of the one or more electric fields to result in a filtered cooling liquid; and causing a flow of the filtered cooling liquid from the electro-filtration device to the cooling chamber.
2: The method for cooling electronic components as clause 1 describes, wherein a magnitude of the one or more electric fields is no less than a threshold value reflecting an electric field caused by the one or more electric components in the cooling chamber.
3: The method for cooling electronic components of clause 1 or 2, wherein filtering at least the portion of the cooling liquid through the electro-filtration device comprises flowing the portion of the cooling liquid that left the cooling chamber through a plurality of substrates, wherein the plurality of electrodes are arranged on the plurality of substrates.
4: The method for cooling electronic components of clause 3, wherein filtering at least the portion of the cooling liquid through the electro-filtration device comprises flowing the portion of the cooling liquid that left the cooling chamber through the plurality of substrates having alternating anodes and cathodes across neighboring substrates, across neighboring electrodes on the same substrate, or both across the neighboring substrates and the neighboring electrodes.
5: The method for cooling electronic components of clause 3 or 4, wherein filtering at least the portion of the cooling liquid through the electro-filtration device comprises flowing the portion of the cooling liquid that left the cooling chamber through the plurality of substrates to pass through through-holes in at least one of the plurality of substrates.
6: The method for cooling electronic components of any of clauses 3-5, wherein filtering at least the portion of the cooling liquid through the electro-filtration device comprises flowing the portion of the cooling liquid that left the cooling chamber through the plurality of substrates having a planar direction of the substrates generally parallel or perpendicular with a direction of a flow of the portion of the cooling liquid that left the cooling chamber.
7: The method for cooling electronic components of any of clauses 1-6, further comprising: measuring a resistance between at least one pair of electrodes of the plurality of electrodes; and comparing an indication based on a measured resistance with a threshold resistance value to identify a condition of the electro-filtration device.
8: The method for cooling electronic components of any of clauses 1-7, further comprising: flowing the cooling liquid that left the cooling chamber through a particle-filtering medium to filter particles in the cooling liquid that left the cooling chamber.
9: The method for cooling electronic components of any of clauses 1-8, further comprising: cooling the one or more electronic components by the thermal exchange between the one or more electronic components and the cooling liquid in the cooling chamber by cooling the one or more electronic components through a vaporization of a heated portion of the cooling liquid in the cooling chamber and through a condensation of a vaporized cooling liquid back into a liquid state by a cooling medium arranged within the cooling chamber.
10: A cooling system comprising: a cooling chamber configured to house at least a portion of a cooling liquid and one or more electronic components arranged along a stacking direction to enable a thermal exchange between the one or more electronic components and the portion of the cooling liquid in the cooling chamber; and a filtration chamber communicatively coupled to the cooling chamber and configured to receive the cooling liquid from the cooling chamber via an inlet portion of the filtration chamber, filter at least a portion of the cooling liquid through the filtration chamber to result in a filtered cooling liquid, and return the filtered cooling liquid in the filtration chamber to the cooling chamber via an outlet portion of the filtration chamber extending along a horizontal direction corresponding to the stacking direction.
11: The cooling system of clause 10, further comprising: a pump configured to cause the flow of the filtered cooling liquid in the filtration chamber to the cooling chamber via the outlet portion of the filtration chamber.
12: The cooling system of clauses 10 or 11, wherein the horizontal direction is parallel to the stacking direction, and the inlet portion or the outlet portion is communicatively coupled to a bottom portion of the cooling chamber.
13: The cooling system of any of clauses 10-12, further comprising: a cooling medium arranged within the cooling chamber, wherein the one or more electronic components are cooled through a vaporization of a heated portion of the cooling liquid in the cooling chamber and through a condensation of a vaporized cooling liquid back into a liquid state by the cooling medium.
14: The cooling system of any of clauses 10-13, further comprising: an electro-filtration device arranged in the filtration chamber, the electro-filtration device comprising a plurality of electrodes providing one or more electric fields while the portion of the cooling liquid flows through at least some of the one or more electric fields to result in the filtered cooling liquid.
15: The cooling system of clause 14, wherein a magnitude of the one or more electric fields is no less than a threshold value reflecting an electric field caused by the one or more electric components in the cooling chamber.
16: The cooling system of clause 14 or 15, wherein the electro-filtration device comprises a plurality of substrates and the plurality of electrodes are arranged on the plurality of substrates.
17: The cooling system of clause 16, wherein the plurality of electrodes comprise alternating anodes and cathodes across neighboring substrates, across neighboring electrodes on the same substrate, or both across the neighboring substrates and the neighboring electrodes.
18: The cooling system of clause 16 or 17, wherein at least one of the plurality of substrates is configured to provide a plurality of through-holes in the at least one of the plurality of substrates.
19: The cooling system of any of clauses 16-18, wherein a planar direction of the plurality of substrates is generally parallel or perpendicular with a direction of a flow of the portion of the cooling liquid within the electro-filtration device.
20: The cooling system of any of clauses 14-19, further comprising: a resistive sensor configured to measure a resistance between at least one pair of electrodes of the plurality of electrodes for comparing a measured resistance between the at least one pair of electrodes of the plurality of electrodes with a threshold resistance value to identify a condition of the electro-filtration device.
21: The cooling system of any of clauses 14-20, wherein a distance between at least one pair of electrodes of the plurality of electrodes is within 0.3 millimeters to 0.6 millimeters.
22: The cooling system of any of clauses 14-21, wherein a magnitude of the one or more electric fields is greater than or equal to 50 volts per millimeter.
23: The cooling system of any of clauses 10-22, further comprising: a particle-filtering medium arranged in the filtration chamber and configured to filter particles in the cooling liquid or the filtered cooling liquid through the filtration chamber.
24: The cooling system of clause 23, further comprising: a plurality of electrodes arranged in the filtration chamber and configured to provide one or more electric fields while the portion of the cooling liquid flows through at least some of the one or more electric fields to result in the filtered cooling liquid, wherein the particle-filtering medium is arranged between a first subset of the plurality of electrodes and a second subset of the plurality of electrodes.
25: An electro-filtration device comprising: an inlet configured to receive a cooling liquid; a plurality of electrodes providing one or more electric fields while a portion of the cooling liquid flows through at least some of the one or more electric fields to result in a filtered cooling liquid; and an outlet configured to release the filtered cooling liquid.
26: The electro-filtration device of clause 25, further comprising: a plurality of substrates, wherein the plurality of electrodes are arranged on the plurality of substrates.
27: The electro-filtration device of clause 26, wherein the plurality of electrodes comprise alternating anodes and cathodes across neighboring substrates, across neighboring electrodes on the same substrate, or both across the neighboring substrates and the neighboring electrodes.
28: The electro-filtration device of clause 26 or 27, wherein at least one of the plurality of substrates is configured to provide a plurality of through-holes in the at least one of the plurality of substrates.
29: The electro-filtration device of any of clauses 26-28, wherein a planar direction of the plurality of substrates is generally parallel or perpendicular with a direction of a flow of the portion of the cooling liquid within the electro-filtration device.
30: The electro-filtration device of any of clauses 25-29, further comprising: a resistive sensor configured to measure a resistance between at least one pair of electrodes of the plurality of electrodes for comparing a measured resistance between the at least one pair of electrodes of the plurality of electrodes with a threshold resistance value to identify a condition of the electro-filtration device.
31: The electro-filtration device of any of clauses 25-30, wherein a distance between at least one pair of electrodes of the plurality of electrodes is within 0.3 millimeters to 0.6 millimeters.
32: The electro-filtration device of any of clauses 25-31, wherein a magnitude of the one or more electric fields is greater than or equal to 50 volts per millimeter.
33: The electro-filtration device as any of clauses 25-32 describe, further comprising: a particle-filtering medium configured to filter particles in the cooling liquid or the filtered cooling liquid.
34: The electro-filtration device of clause 33, wherein the particle-filtering medium is arranged between a first subset of the plurality of electrodes and a second subset of the plurality of electrodes.

The foregoing outlines exemplary features of several embodiments for illustration, so that those skilled in the art may understand exemplary aspects of the present disclosure. Those skilled in the art may readily use the present disclosure as a basis for designing or modifying other processes and structures for carrying out the same or similar purposes and/or achieving the same or overlapping advantages of the exemplary embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for cooling electronic components, the method comprising:
causing a flow of a portion of a cooling liquid from a cooling chamber through an electro-filtration device, wherein the cooling chamber is configured to enable a thermal exchange between one or more electronic components and the cooling liquid housed in the cooling chamber;
filtering at least a portion of the cooling liquid through the electro-filtration device, which is configured to apply one or more electric fields on the portion of the cooling liquid, the electro-filtration device having a plurality of electrodes for providing the one or more electric fields while the portion of the cooling liquid flows through at least some of the one or more electric fields to result in a filtered cooling liquid; and
causing a flow of the filtered cooling liquid from the electro-filtration device to the cooling chamber.

2. The method for cooling electronic components of claim 1, wherein a magnitude of the one or more electric fields is no less than a threshold value reflecting an electric field caused by the one or more electric components in the cooling chamber.

3. The method for cooling electronic components of claim 1, wherein filtering at least the portion of the cooling liquid through the electro-filtration device comprises flowing the portion of the cooling liquid that left the cooling chamber through a plurality of substrates, wherein the plurality of electrodes are arranged on the plurality of substrates.

4. The method for cooling electronic components of claim 3, wherein filtering at least the portion of the cooling liquid through the electro-filtration device comprises flowing the portion of the cooling liquid that left the cooling chamber through the plurality of substrates having alternating anodes and cathodes across neighboring substrates, across neighboring electrodes on the same substrate, or both across the neighboring substrates and the neighboring electrodes.

5. The method for cooling electronic components of claim 3, wherein filtering at least the portion of the cooling liquid through the electro-filtration device comprises flowing the portion of the cooling liquid that left the cooling chamber through the plurality of substrates to pass through through-holes in at least one of the plurality of substrates.

6. The method for cooling electronic components of claim 3, wherein filtering at least the portion of the cooling liquid through the electro-filtration device comprises flowing the portion of the cooling liquid that left the cooling chamber through the plurality of substrates having a planar direction of the substrates generally parallel or perpendicular with a direction of a flow of the portion of the cooling liquid that left the cooling chamber.

7. The method for cooling electronic components of claim 1, further comprising:
measuring a resistance between at least one pair of electrodes of the plurality of electrodes; and
comparing a measured resistance with a threshold resistance value to identify a condition of the electro-filtration device.

8. The method for cooling electronic components of claim 1, further comprising:
flowing the cooling liquid that left the cooling chamber through a particle-filtering medium to filter particles in the cooling liquid that left the cooling chamber.

9. The method for cooling electronic components of claim 1, further comprising:
cooling the one or more electronic components by the thermal exchange between the one or more electronic components and the cooling liquid in the cooling chamber by cooling the one or more electronic components through a vaporization of a heated portion of the cooling liquid in the cooling chamber and through a condensation of a vaporized cooling liquid back into a liquid state by a cooling medium arranged within the cooling chamber.

10. A cooling system comprising:
a cooling chamber configured to house at least a portion of a cooling liquid and one or more electronic components arranged along a stacking direction to enable a thermal exchange between the one or more electronic components and the portion of the cooling liquid in the cooling chamber; and
a filtration chamber communicatively coupled to the cooling chamber and configured to receive the cooling liquid from the cooling chamber via an inlet portion of the filtration chamber, filter at least a portion of the cooling liquid through the filtration chamber to result in a filtered cooling liquid, and return the filtered cooling liquid in the filtration chamber to the cooling chamber via an outlet portion of the filtration chamber extending along a horizontal direction corresponding to the stacking direction.

11. The cooling system of claim 10, further comprising:
a pump configured to cause the flow of the filtered cooling liquid in the filtration chamber to the cooling chamber via the outlet portion of the filtration chamber.

12. The cooling system of claim 10, wherein the horizontal direction is parallel to the stacking direction, and the inlet portion or the outlet portion is communicatively coupled to a bottom portion of the cooling chamber.

13. The cooling system of claim 10, further comprising:
a cooling medium arranged within the cooling chamber, wherein the one or more electronic components are cooled through a vaporization of a heated portion of the cooling liquid in the cooling chamber and through a condensation of a vaporized cooling liquid back into a liquid state by the cooling medium.

14. The cooling system of claim 10, further comprising:
an electro-filtration device arranged in the filtration chamber, the electro-filtration device comprising a plurality of electrodes providing one or more electric fields while the portion of the cooling liquid flows through at least some of the one or more electric fields to result in the filtered cooling liquid.

15. The cooling system of claim 14, wherein a magnitude of the one or more electric fields is no less than a threshold value reflecting an electric field caused by the one or more electric components in the cooling chamber.

16. The cooling system of claim 14, wherein the electro-filtration device comprises a plurality of substrates and the plurality of electrodes are arranged on the plurality of substrates.

17. The cooling system of claim 16, wherein the plurality of electrodes comprise alternating anodes and cathodes across neighboring substrates, across neighboring electrodes on the same substrate, or both across the neighboring substrates and the neighboring electrodes.

18. The cooling system of claim 16, wherein at least one of the plurality of substrates is configured to provide a plurality of through-holes in the at least one of the plurality of substrates.

19. The cooling system of claim 16, wherein a planar direction of the plurality of substrates is generally parallel or perpendicular with a direction of a flow of the portion of the cooling liquid within the electro-filtration device.

20. The cooling system of claim 14, further comprising:
a resistive sensor configured to measure a resistance between at least one pair of electrodes of the plurality of electrodes for comparing a measured resistance between the at least one pair of electrodes of the plurality of electrodes with a threshold resistance value to identify a condition of the electro-filtration device.

21. The cooling system of claim 14, wherein a distance between at least one pair of electrodes of the plurality of electrodes is within 0.3 millimeters to 0.6 millimeters.

22. The cooling system of claim 14, wherein a magnitude of the one or more electric fields is greater than or equal to 50 volts per millimeter.

23. The cooling system of claim 10, further comprising:
a particle-filtering medium arranged in the filtration chamber and configured to filter particles in the cooling liquid or the filtered cooling liquid through the filtration chamber.

24. The cooling system of claim 23, further comprising:
a plurality of electrodes arranged in the filtration chamber and configured to provide one or more electric fields while the portion of the cooling liquid flows through at least some of the one or more electric fields to result in the filtered cooling liquid, wherein the particle-filtering medium is arranged between a first subset of the plurality of electrodes and a second subset of the plurality of electrodes.

25. An electro-filtration device comprising:
an inlet configured to receive a cooling liquid;
a plurality of electrodes providing one or more electric fields while a portion of the cooling liquid flows through at least some of the one or more electric fields to result in a filtered cooling liquid; and
an outlet configured to release the filtered cooling liquid.

26. The electro-filtration device of claim 25, further comprising:
a plurality of substrates, wherein the plurality of electrodes are arranged on the plurality of substrates.

27. The electro-filtration device of claim 26, wherein the plurality of electrodes comprise alternating anodes and cathodes across neighboring substrates, across neighboring electrodes on the same substrate, or both across the neighboring substrates and the neighboring electrodes.

28. The electro-filtration device of claim 26, wherein at least one of the plurality of substrates is configured to provide a plurality of through-holes in the at least one of the plurality of substrates.

29. The electro-filtration device of claim 26, wherein a planar direction of the plurality of substrates is generally parallel or perpendicular with a direction of a flow of the portion of the cooling liquid within the electro-filtration device.

30. The electro-filtration device of claim 25, further comprising:
a resistive sensor configured to measure a resistance between at least one pair of electrodes of the plurality of electrodes for comparing a measured resistance between the at least one pair of electrodes of the plurality of electrodes with a threshold resistance value to identify a condition of the electro-filtration device.

31. The electro-filtration device of claim 25, wherein a distance between at least one pair of electrodes of the plurality of electrodes is within 0.3 millimeters to 0.6 millimeters.

32. The electro-filtration device of claim 25, wherein a magnitude of the one or more electric fields is greater than or equal to 50 volts per millimeter.

33. The electro-filtration device of claim 25, further comprising:
a particle-filtering medium configured to filter particles in the cooling liquid or the filtered cooling liquid.

34. The electro-filtration device of claim 33, wherein the particle-filtering medium is arranged between a first subset of the plurality of electrodes and a second subset of the plurality of electrodes.
